(19) United States
(12) Patent Application Publication
(10) Pub. No.: US 2026/0371664 A1
(43) Pub. Date: Nov. 19, 2026

(54) SEMICONDUCTOR DEVICE

(71) Applicant: Fast SiC Semiconductor Incorporated, Hsinchu City (TW)

(72) Inventors: Ting-Fu CHANG, Hsinchu City (TW); Fu-Jen HSU, Hsinchu City (TW); Cheng-Tyng YEN, Hsinchu City (TW)

(21) Appl. No.: 19/211,363

(22) Filed: May 19, 2025

(51) Int. Cl. H10D 62/10; H10D 8/60; H10D 62/60

(52) U.S. Cl. CPC H10D 62/107; H10D 8/60; H10D 62/124; H10D 62/60

(57) ABSTRACT

A semiconductor device comprises a semiconductor body, a first doped region, and a second doped region. The semiconductor body has a first conductivity type. The first doped region and second doped region are disposed in the semiconductor body and have second conductivity type. The first doped region is adjacent to a main surface of the semiconductor body, and the second doped region is arranged below the first doped region. The first doped region and the second doped region are laterally extended, and the first doped region is partially positioned above the second doped region, thereby forming a lateral channel region in the semiconductor body and between the first doped region and the second doped region.

### FIELD OF THE INVENTION

The present disclosure relates to a semiconductor device and more particularly to a semiconductor device with a lateral channel region to achieve a controllable forward threshold voltage.

### BACKGROUND OF THE INVENTION

Semiconductor devices are fundamental components in modern electronic systems, applicated in various fields such as power electronics, communication systems, automotive electronics, and consumer electronics. These devices are integral in controlling the flow of electrical current, often serving critical roles in rectification, switching, and amplification functions. Among the many types of semiconductor devices, Schottky Barrier Diodes (SBDs) and Junction Field-Effect Transistors (JFETs) are commonly used for the fast switching speeds and low forward voltage drop.

However, conventional semiconductor devices, such as Schottky Barrier Diodes, face a limitation in controlling the threshold voltage of the forward voltage, which is fixed during fabrication and is difficult to adjust. This lack of flexibility restricts the adaptability of these devices for various applications where specific threshold voltages are needed to optimize performance. Consequently, there is a need for semiconductor devices that allow for more flexible control over their electrical characteristics, particularly the ability to adjust the threshold voltage.

### SUMMARY OF THE INVENTION

In view of this, it is necessary to provide an improved semiconductor device to reduce on-state resistance without deficiencies related to the breakdown voltage and a method for fabricating the same.

An objective of the invention is to provide a semiconductor device, which can improve the controllability of the threshold voltage of the forward voltage.

An example of the present disclosure relates to a semiconductor device. The semiconductor device comprises a semiconductor body, a first doped region, and a second doped region. The semiconductor body has a first conductivity type. The first doped region has a second conductivity type and is disposed in the semiconductor body. The first doped region is adjacent to a main surface of the semiconductor body. The second doped region has the second conductivity type and is disposed in the semiconductor body. The second doped region is arranged below the first doped region. The first doped region and the second doped region are laterally extended, and the first doped region is partially positioned above the second doped region, thereby forming a lateral channel region in the semiconductor body and between the first doped region and the second doped region.

Other objectives, features and advantages of the invention will be further understood from the further technological features disclosed by the embodiments of the invention wherein there are shown and described preferred embodiments of this invention, simply by way of illustration of modes best suited to carry out the invention.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a cross-sectional view of a semiconductor device according to a first embodiment of the present disclosure.

FIG. 2 is a cross-sectional view of the semiconductor device according to a second embodiment of the present disclosure.

FIG. 3 is a cross-sectional view of the semiconductor device according to a third embodiment of the present disclosure.

FIG. 4 is a cross-sectional view of the semiconductor device according to a fourth embodiment of the present disclosure.

FIG. 5 is a cross-sectional view of the semiconductor device according to a fifth embodiment of the present disclosure.

FIG. 6 is an example of I-V characteristic curves in accordance with one embodiment of the present disclosure.

### DETAILED DESCRIPTION OF THE PREFERRED

EMBODIMENT S

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure.

As used herein, the term “and/or” includes any and all combinations of one or more of the associated listed items.

In the drawings, the thickness of layers and regions are exaggerated for clarity. It will also be understood that when an element such as a layer, portion, region, or substrate is referred to as being “on”, “overlie” or “atop” another element, it can be directly on, directly overlie or directly atop the other element or intervening elements may also be present. In contrast, when an element is referred to as being “directly on”, “directly overlie” or “directly atop” another element, there are no intervening elements present.

Relative terms may be used herein to describe a relationship of one element, layer, portion, or region to another element, layer, portion, or region as illustrated in the figures. It will be understood that these terms and those discussed above are intended to encompass different orientations of the device in addition to the orientation depicted in the figures. A number of embodiments will be explained below, identical structural features are identified by identical or similar reference symbols in the figures. As used herein, “lateral” or “lateral direction” should be understood to mean a direction or extent that runs generally parallel to the lateral extent of the semiconductor device. The term “lateral” or “lateral direction” is not limit to a strictly horizontal orientation but may also include directions that are inclined at a certain angle.

The terminology used herein is for the purpose of describing particular embodiments only and is not intended to be limiting of the disclosure. As used herein, the singular forms “a”, “an”, and “the” are intended to include the plural forms as well, unless the context clearly indicates otherwise. It will be further understood that the terms “comprises”, “comprising”, “includes”, and/or “including” when used herein specify the presence of stated features, elements, and/or components, but do not preclude the presence or addition of one or more other features, elements, components, and/or groups thereof. The indefinite articles and the definite articles shall encompass both the plural and singular unless the opposite is clearly apparent from the context.

In this specification, n-doped is referred to as first conductivity type while p-doped is referred to as second conductivity type. Alternatively, the semiconductor devices can be formed with opposite doping relations so that the first conductivity type can be p-doped and the second conductivity type can be n-doped. Furthermore, some Figures illustrate relative doping concentrations by indicating “−” or “+” next to the doping type. For example, “n−” means a doping concentration which is less than the doping concentration of an “n”-doping region while an “n+”-doping region has a larger doping concentration than the “n”-doping region. However, indicating the relative doping concentration does not mean that doping regions of the same relative doping concentration have to have the same absolute doping concentration unless otherwise stated. For example, two different n+-doping regions can have different absolute doping concentrations. The same applies, for example, to an n+-doping and a p+-doping region.

While properties, materials, dimensions, shapes, positional interrelationships, conditions for implementation, or the like of respective components have been described in the present disclosure, those are mere examples in all aspects, and each of the embodiments is not limited to those described. Accordingly, numerous modifications which are not illustratively described are conceivable within the scope of each of the embodiments.

The semiconductor device described herein may be fabricated using various semiconductor materials, including but not limited to silicon carbide (SiC) or silicon (Si). The device is adaptable to multiple configurations and functionalities, such as metal-oxide-semiconductor field effect transistors (MOSFET), insulated gate bipolar transistors (IGBT), heterostructure field effect transistors (HFET), junction field effect transistors (JFET) and high electron mobility transistors (HEMT), a rectifier, or other semiconductor components. The rectifier structure is provided below as a non-limiting example.

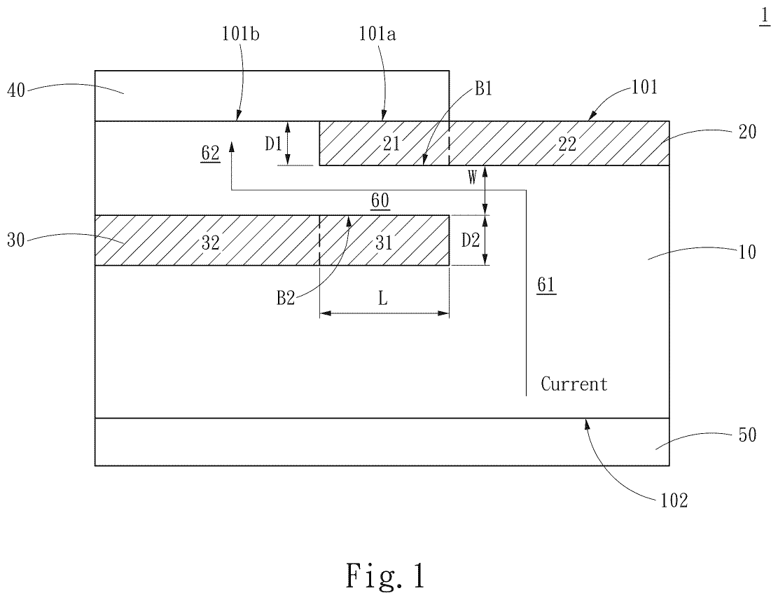

FIG. 1 shows a cross-sectional view of a first embodiment of a semiconductor device 1. The semiconductor device 1 comprises a semiconductor body 10, a first doped region 20, a second doped region 30, a first electrode 40 and a second electrode 50.

The semiconductor body 10 may be or include a semiconductor substrate. The semiconductor substrate may be silicon carbide or silicon materials and has a first conductivity type (e.g., N-type) with a dopant concentration. In some examples, the semiconductor body 10 may include the semiconductor substrate with other layers or structures disposed on the semiconductor substrate. The first doped region 20 is disposed in the semiconductor body 10 and adjacent to a main surface 101 of the semiconductor body 10. The first doped region 20 has a second conductivity type (e.g., P-type), which is opposite to the first conductivity type. The first doped region 20 is formed by implanting group III atoms (e.g., aluminum ions) as dopants into an N-type semiconductor body to form a counter-doped P-type region at a top of the semiconductor body 10 and adjoining the main surface 101 of the semiconductor body 10. A thickness D1 of the first doped region 20 may be adjusted and controlled by the implanting process. The thickness D1 may be a constant value over a horizontal direction such that the first doped region 20 is formed as a planar structure. In an example, the thickness D1 of the first doped region 20 is less than 2 μm. Alternatively, the thickness D1 may vary over a horizontal direction such that the first doped region 20 is formed as a staircase-like, tapered or graded contours.

The second doped region 30 is disposed in the semiconductor body 10 and is arranged below the main surface 101 of the semiconductor body 10. The second doped region 30 has the second conductivity type (e.g., P-type) with a doping concentration that may be either the same as or different from that of the first doped region 20. The second doped region 30 is formed by implanting group III atoms (e.g., aluminum ions) as dopants into the N-type semiconductor body to form a counter-doped P-type region at a depth greater than that of the first doped region 20. A thickness D2 of the second doped region 30 may be a constant value over a horizontal direction such that the second doped region 30 is formed as a plate structure. In an example, the thickness D2 of the second doped regions 30 is less than 2μm. Alternatively, the thickness D2 of the second doped region 30 may vary over a horizontal direction such that the second doped region 30 is formed as a staircase-like, tapered or graded contours.

Both the first doped region 20 and the second doped region 30 extend laterally, namely, along a direction parallel to the main surface 101 of the semiconductor body 10. The second doped region 30 is extended horizontally below the first doped region 20. That is, the first doped region 20 and the second doped region 30 are formed across a different depth range of the semiconductor body 10. On another hand, the first doped region 20 is partially positioned above the second doped region 30 and spaced with each other at a vertical distance.

The first doped region 20 may be extended from the main surface 101 to a maximum depth that is equal to the thickness D1 below the main surface 101. The second doped region 30 may be extended from a minimum depth to a maximum depth. The difference between the minimum depth and the maximum depth of the second doped region 30 is the thickness D2. In the example, the maximum depth of the first doped region 20 is less than either of the minimum depth or the maximum depth of the second doped region 30.

The first doped region 20 may comprise a first portion 21 and the second portion 22, and the second doped region 30 comprises a third portion 31 and a fourth portion 32. The first portion 21 of the first doped region 20 corresponds to the third portion 31 of the second doped region 30. The first portion 21 is situated over the third portion 31 with a gap to form a lateral channel region 60 therebetween. The lateral channel region 60 is formed with a lateral extension of the first portion 21 and the third portion 31. The second portion 22 of the first doped region 20 is defined as a portion that laterally extends from the first portion 21, where no second doped region 30 is formed below. Similarly, the fourth portion 32 of the second doped region 30 is defined as a portion that laterally extends from the third portion 31, where no first doped region 20 is formed above.

The first doped region 20 and the second doped region 30 are vertically spaced apart from each other so that a vertical separation width W is provided therebetween. The vertical separation width W may be less than 5 μm, or more preferably, less than 1 μm. The first doped region 20 partially overlies the second doped region 30, more particularly, the first portion 21 of the first doped region 20 overlies the third portion 31 of the second doped region 30. In an example, a length L of the overlying portion (e.g. the first portion 21 or the third portion 31) may be less than 10 μm.

The lateral channel region 60 is formed between the first portion 21 of the first doped region 20 and the third portion 31 of the second doped region 30. The lateral channel region 60 is a channel with the first conductivity type sandwiched by the first doped region 20 and the second doped region 30 with the second conductivity type. The lateral channel region 60 is a planar configuration extended horizontally. The configuration of the lateral channel region 60 is dependent with the formation of the first doped region 20 and the second doped region 30. That is, a bottom boundary B1 of the first portion 21 and an upper boundary B2 of the third portion 31 determine the configuration of the lateral channel region 60. For example, the lateral channel region 60 may be an inclined planar configuration or a ladder-like configuration.

By forming the lateral channel region 60, when a forward bias voltage is applied on the semiconductor device 1, a current will flow from the second electrode 50 through the lateral channel region 60, which is formed between the first portion 21 of the first doped region 20 and the third portion 31 of the second doped region 30, to the first electrode 40. When the forward voltage exceeds a threshold voltage, a pinch-off occurs to limit the current to a specific value to pass through, thereby achieving a rectification effect. The threshold voltage of the semiconductor device 1 is able to be easily controlled by adjusting the value of the vertical separation width W between the first doped region 20 and the second doped region 30.

The first electrode 40 is disposed on a first area 101a and a second area 101b of the semiconductor body 10 and electrically connects the first doped region 20. In the example, the first electrode 40 is extended to dispose above the entire lateral channel region 60 (or overlay the first doped region 20). In other example, the first electrode 40 may be laterally extended over the lateral channel region 60 or extended to dispose above the partial lateral channel region 60. The first electrode 40 may be a cathode metal layer that includes a metal, such as titanium, aluminum, or nickel, that is suitable for forming an Ohmic contact or a Schottky contact with the first doped region 20. The second electrode 50 is formed on a back surface 102 of the semiconductor body 10 which is opposite to the main surface 101. The second electrode 50 may be an anode metal layer includes a metal, such as titanium, aluminum, or nickel, that is suitable for forming an Ohmic contact or a Schottky contact electrically connects to the semiconductor body 10. In some examples, the first electrode 40 and/or the second electrode 50 may be independently formed by one or more materials with one or more doping concentrations.

The first doped region 20 is formed along the first area 101a of the main surface 101, while the second area 101b, adjacent to the first area 101a, is provided on the main surface 101 of the semiconductor body 10, where the first doped region 20 is not present. The third portion 31 of the second doped region 30 is positioned below the first area 101a and is vertically separated from the first portion 21 of the first doped region 20 to allow the lateral channel region 60 to be created. The second portion 22 of the first doped region 20 is positioned above the back surface 102 (or the second electrode 50), where the second doped region 30 is not present below the second portion 22. The fourth portion 32 is positioned below the second area 101b, where the first doped region 20 is not present above the fourth portion 32. Therefore, the current may follow a first vertical channel region 61, the lateral channel region 60 and then the second vertical channel region 62 when the voltage is applied across the first electrode 40 and the second electrode 50.

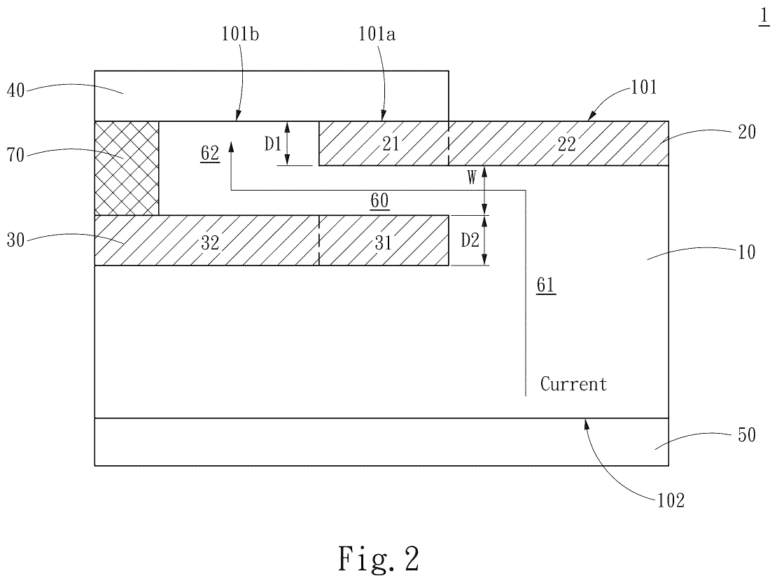

In the example of FIG. 2, the semiconductor device 1 may further comprise a connection region 70, which is formed between the first electrode 40 and the second doped region 30 such that the first electrode 40 is in direct contact with the first doped region 20 on the main surface 101 and indirectly contact with the second doped region 30 through the connection region 70.

In one example, the connection region 70 may be formed by embedding a conductive material, such as metals, metal nitrides, metal silicide, and metal silicide nitrides, into a trench fabricated within the semiconductor body 10 and extended from the main surface 101 to the second doped region 30, and the conductive material in the trench. In an alternative example, the connection region 70 may be formed by introducing dopants into the N-type semiconductor body to form a third doped region. The dopants may be any metals or atoms from groups III and V that can generate an electrical potential difference between the first electrode 40 and the second doped region 30.

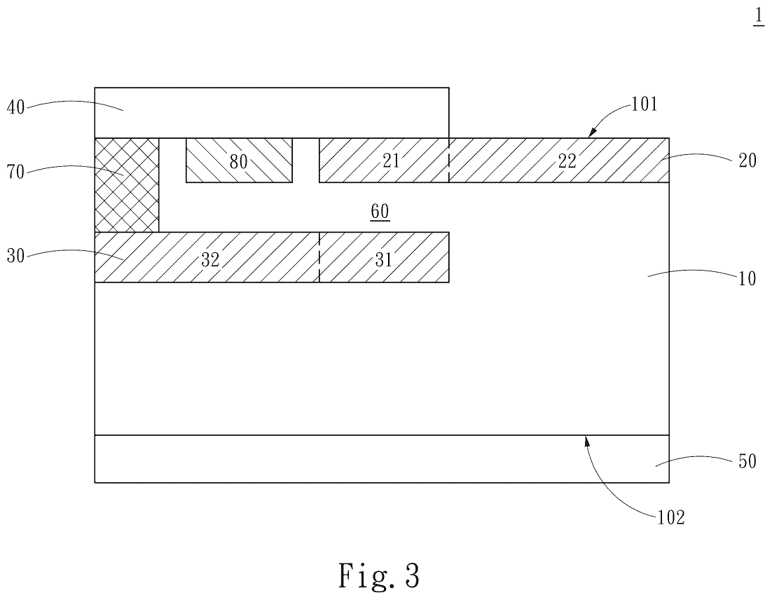

In the example of FIG. 3, an additional doped region 80 may be disposed in the semiconductor body 10 beneath the first electrode 40 and positioned above the fourth portion 32 of the second doped region 30. The additional doped region 80 facilitates forming the Ohmic contact.

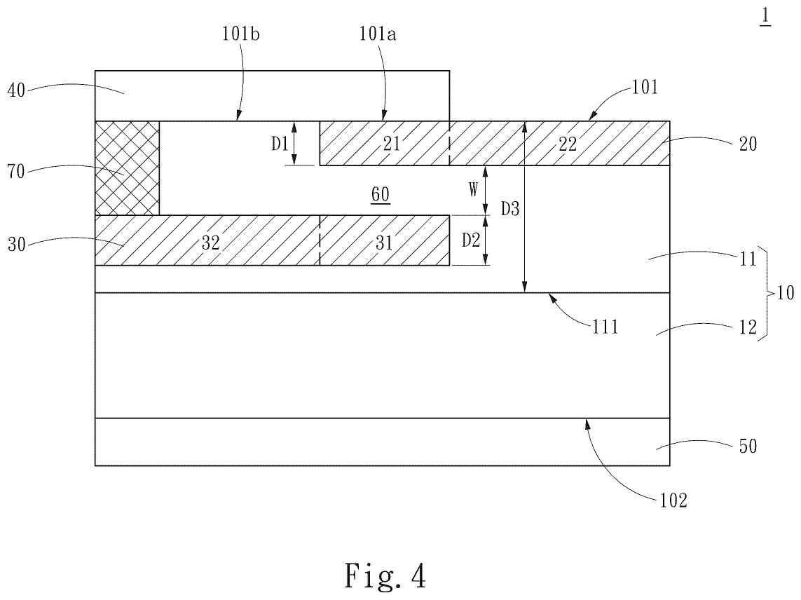

Referring to FIG. 4, the semiconductor body 10 may comprise multiple layers with different dopant concentrations. The semiconductor body 10 comprises a first concentration region 11 and a second concentration region 12, wherein a dopant concentration of the first concentration region 11 is higher than that of the second concentration region 12. In one example, the dopant concentration of the first concentration region 11 or the second concentration region 12 may be uniform. In another example, the dopant concentration of the first concentration region 11 or the second concentration region 12 may be gradually changed along a thickness direction.

In this example, the first concentration region 11 is disposed on the top of the second concentration region 12, and the second concentration region 12 is positioned at a deeper location within the semiconductor body 10 than the first doped region 20 and the second doped region 30.

As shown in FIG. 4, an interface 111 between the first concentration region 11 and the second concentration region 12 is positioned deeper than the bottom of the second doped region 30, and a thickness D3 of the first concentration region 11 is greater than the sum of the thickness D1 of the first doped region 20, the thickness D2 of the second doped region 30, and the vertical separation width W. The first doped region 20 and the second doped region 30 are both disposed in the first concentration region 11.

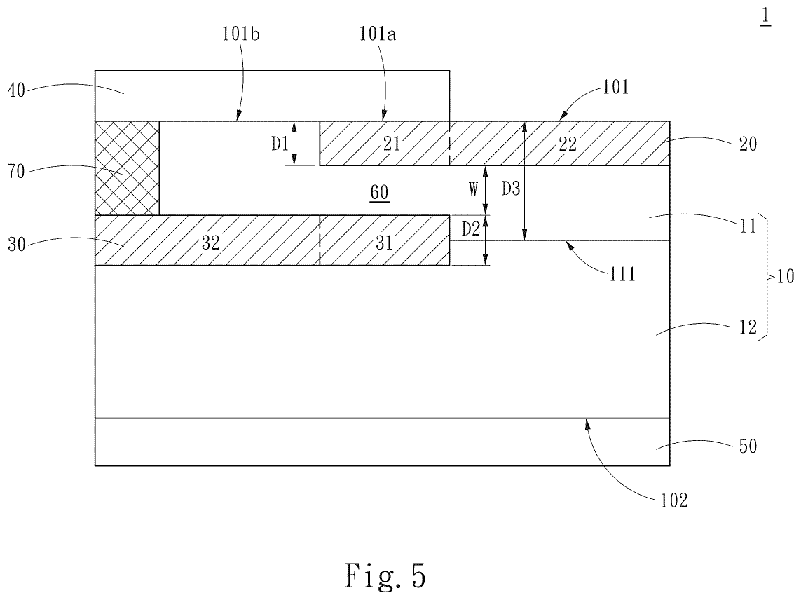

Referring to FIG. 5, the interface 111 is positioned shallower than the bottom of the second doped region 30, and the thickness D3 of the first concentration region 11 is smaller than the sum of the thickness D1 of the first doped region 20, the thickness D2 of the second doped region 30, and the vertical separation width W. The first doped region 20 is disposed in the first concentration region 11, and the second doped region 30 is disposed in both the first concentration region 11 and the second concentration region 12.

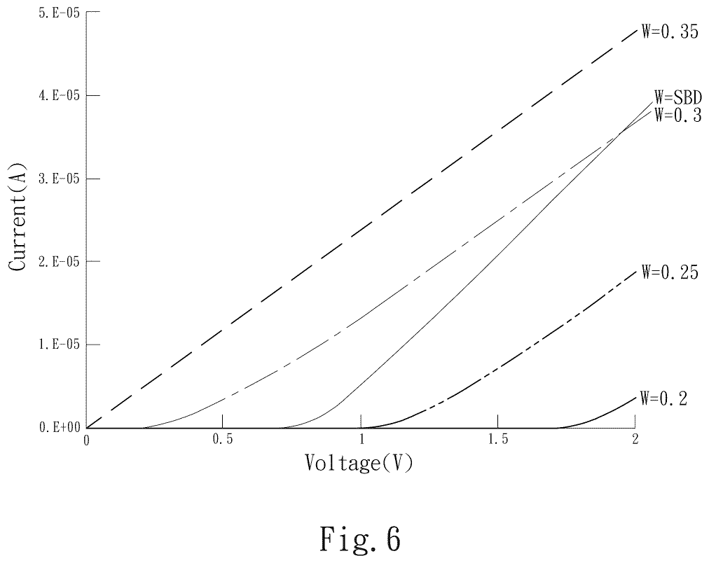

FIG. 6 shows I-V characteristic curves of a typical Schottky barrier diode (SBD) semiconductor and a rectifier with a structure according to the present disclosure under different values (e.g. 0.2 μm, 0.25 μm, 0.3 μm, 0.35 μm) of the vertical separation width W. Comparing with the typical SBD semiconductor which threshold voltage is fixed and uncontrollable, the threshold voltage of the semiconductor device 1 of the present disclosure can be easily controlled by adjusting the value of the vertical separation width W. As can be seen from FIG. 6, a reduction in the vertical separation width W results in a higher threshold voltage, demonstrating the ability of the present disclosure to control the electrical characteristics tuning the distance between the first doped region 20 and the second doped region 30.

What is claimed is:

1. A semiconductor device, comprising:
a semiconductor body having a first conductivity type;
a first doped region of a second conductivity type disposed in the semiconductor body, wherein the first doped region is adjacent to a main surface of the semiconductor body; and
a second doped region of the second conductivity type disposed in the semiconductor body, the second doped region is arranged below the first doped region;
wherein the first doped region and the second doped region are laterally extended, and the first doped region is partially positioned above the second doped region, thereby forming a lateral channel region in the semiconductor body and between the first doped region and the second doped region.

2. The semiconductor device of claim 1, wherein the first doped region has a first portion positioned above the second doped region and the second doped region has a fourth portion not overlapped by the first doped region, wherein a first electrode is formed on an area of the main surface positioned above the fourth portion.

3. The semiconductor device of claim 2, wherein a second electrode is formed on a back surface opposite the main surface, and the first doped region has a second portion positioned above the back surface.

4. The semiconductor device of claim 1, wherein the second doped region is deeper than the first doped region.

5. The semiconductor device of claim 1, wherein a portion of the first doped region is positioned above the second doped region with no vertical contact, and the portion laterally extends beneath an area of the main surface of the semiconductor body.

6. The semiconductor device of claim 5, wherein the portion has a length less than 10 μm.

7. The semiconductor device of claim 1, wherein the first doped region and the second doped region electrically connect to a first electrode disposed on the semiconductor body, and wherein a bottom of the semiconductor body electrically connects to a second electrode.

8. The semiconductor device of claim 7, wherein current flows laterally through the lateral channel region when a voltage is applied across the first electrode and the second electrode.

9. The semiconductor device of claim 7, wherein further comprises a connection region electrically connected between the first electrode and the second doped region.

10. The semiconductor device of claim 9, wherein further comprises a trench formed in the semiconductor body, and wherein the connection region is formed by a conductive material embedded in the trench.

11. The semiconductor device of claim 9, wherein the connection region is formed by a third doped region disposed in the semiconductor body.

12. The semiconductor device of claim 1, wherein the semiconductor body includes a first concentration region and a second concentration region with a dopant concentration different from the first concentration region.

13. The semiconductor device of claim 12, wherein the first doped region and the second doped region are disposed within the first concentration region.

14. The semiconductor device of claim 12, wherein the first concentration region has a dopant concentration higher than the second concentration region.

15. The semiconductor device of claim 12, wherein a doping concentration in the first concentration region and the second concentration region is gradually changed along a thickness direction.

16. The semiconductor device of claim 12, wherein the second concentration region is deeper than the first doped region and the second doped region.

17. The semiconductor device of claim 1, wherein a vertical separation width is provided between the first doped region and the second doped region.

18. The semiconductor device of claim 17, wherein the vertical separation width is less than 5 μm.

19. The semiconductor device of claim 1, wherein the first doped region has a thickness less than 2 μm.

20. The semiconductor device of claim 1, wherein the second doped region has a thickness less than 2 μm.
